(19) United States
(12) Patent Application Publication
(10) Pub. No.: US 2009/0096003 A1
(43) Pub. Date: Apr. 16, 2009

(54) SEMICONDUCTOR CELL STRUCTURE INCLUDING BURIED CAPACITOR AND METHOD FOR FABRICATION THEREOF

(75) Inventor: Huilong Zhu, Poughkeepsie, NY (US)

Correspondence Address: SCULLY, SCOTT, MURPHY & PRESSER, P.C., 400 GARDEN CITY PLAZA, Suite 300, GARDEN CITY, NY, 11530, US

(73) Assignee: INTERNATIONAL BUSINESS MACHINES CORPORATION, Armonk, NY (US)

(21) Appl. No.: 11/870,584

(22) Filed: Oct. 11, 2007

(51) Int. Cl. H01L 27/108; H01L 21/8242

(52) U.S. Cl. 257/309; 438/255; 257/E27.084; 257/E21.646

(57) ABSTRACT

A semiconductor structure and a method for fabricating the semiconductor structure include at least one field effect transistor, and also a capacitor, located over a substrate. In particular, the capacitor is located interposed between the field effect transistor and the substrate. The field effect transistor may include a planar field effect transistor as well as a fin-FET. The capacitor may be connected with a conductor plug layer to a source/drain region of the field effect transistor to form a dynamic random access memory cell structure.

### BACKGROUND

1. Field of the Invention

The invention relates generally to semiconductor structures. More specifically, the invention relates to space efficient semiconductor structures.

2. Description of the Related Art

Semiconductor circuits include semiconductor structures that include devices such as resistors, transistors, diodes and capacitors. The devices are connected and interconnected using patterned conductor layers that are separated by dielectric layers.

A particularly common semiconductor structure is a memory cell structure, such as a dynamic random access memory cell structure. A dynamic random access memory cell structure generally includes a field effect transistor that has a storage capacitor connected to one of the source/drain regions of the field effect transistor. Dynamic random access memory cell structures have been successfully scaled for several decades to increasingly smaller dimensions that allow for reducing manufacturing costs and increasing levels of integration within the dynamic random access memory cell structures.

While dynamic random access memory cell structures have been successfully scaled for several decades, the scaling of dynamic random access memory cell structures is not entirely without problems. In particular, such scaling, while physically achievable for both a field effect transistor and a storage capacitor within a dynamic random access memory cell structure, is problematic for the storage capacitor insofar as storage capacitors when aggressively scaled may not have adequate storage capacitance for proper operation of a dynamic random access memory cell structure. In addition, gate length scaling of field effect transistors increases leakage current due to short channel effects, which requires large storage capacitance for given retention time requirement. Various dynamic random access memory cell structures having desirable properties have been disclosed in the semiconductor fabrication art.

For example, Ema, in U.S. Pat. No. 6,528,369 teaches a dynamic random access memory cell structure that includes a multi-layered capacitor node within a capacitor that comprises the dynamic random access memory cell structure. The multi-layered capacitor node provides for enhanced storage capacitance within the storage capacitor within the dynamic random access memory cell structure.

In addition, Fried at al., in U.S. Pat. No. 6,664,582 teaches another dynamic random access memory structure and a related method for fabricating the dynamic random access memory cell structure. This particular dynamic random access memory cell structure includes a fin-FET structure and a contiguous fin-capacitor structure.

Semiconductor device and semiconductor structure dimensions are certain to continue to decrease as semiconductor device technology advances. Thus, desirable are dynamic random access memory cell structures having enhanced performance at decreased dimensions.

### SUMMARY

The invention includes a semiconductor structure that may comprise a dynamic random access memory cell structure, as well as a method for fabricating the semiconductor structure. The semiconductor structure includes a field effect transistor structure that is located over, and preferably connected with, a capacitor structure within the semiconductor structure.

A particular semiconductor structure in accordance with the invention includes a field effect transistor located over a substrate. The particular semiconductor structure also includes a capacitor located over the substrate and interposed between the field effect transistor and the substrate.

A particular method for fabricating a semiconductor structure in accordance with the invention includes forming a capacitor over a substrate. This particular method also includes forming a field effect transistor over the substrate and over the capacitor.

Another particular method for fabricating a semiconductor structure in accordance with the invention includes forming a capacitor over a substrate. This other particular method also includes forming a first field effect transistor over the substrate and over the capacitor. This other method also includes forming a second field effect transistor over the substrate and over the capacitor.

### BRIEF DESCRIPTION OF THE DRAWINGS

The objects, features and advantages of the invention are understood within the context of the Description of the Preferred Embodiment, as set forth below. The Description of the Preferred Embodiment is understood within the context of the accompanying drawings, which form a material part of this disclosure, wherein:

FIG. 1 to FIG. 12 show a series of schematic cross-sectional diagrams illustrating the results of progressive stages in fabricating a semiconductor structure (i.e., in particular a dynamic random access memory cell structure) in accordance with a particular embodiment of the invention.

FIG. 13 shows a schematic cross-sectional diagram illustrating a semiconductor structure (i.e., a dynamic random access memory cell structure) in accordance with another embodiment of the invention.

FIG. 14 to FIG. 20 show a series of schematic cross-sectional diagrams illustrating the result of progressive stages in fabricating a semiconductor structure (i.e., a dynamic random access memory cell structure) in accordance with a yet another embodiment of the invention.

### DESCRIPTION OF THE PREFERRED EMBODIMENTS

The invention, which includes a semiconductor structure that may comprise a dynamic random access memory cell structure, as well as a method for fabricating the semiconductor structure, is understood within the context of the description as set forth below. The description as set forth below is understood within the context of the drawings described above. Since the drawings are intended for illustrative purposes, the drawings are not necessarily drawn to scale.

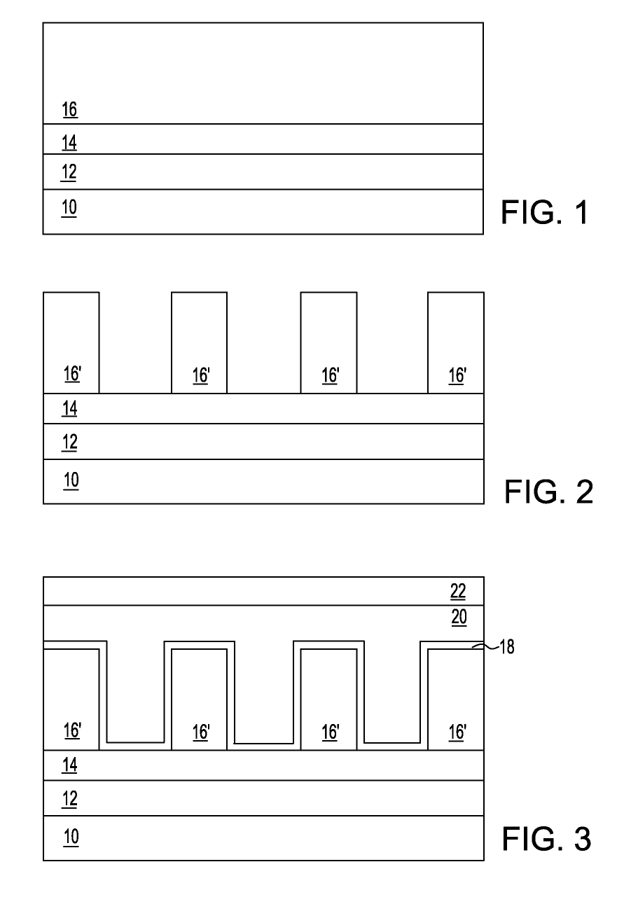

FIG. 1 to FIG. 12 show a series of schematic cross-sectional diagrams illustrating the results of progressive stages in fabricating a semiconductor structure (i.e., a dynamic random access memory semiconductor structure) in accordance with a particular embodiment of the invention. This particular embodiment of the invention comprises a first embodiment of the invention. FIG. 1 shows a schematic cross-sectional diagram of the semiconductor structure at an early stage in the fabrication thereof in accordance with this particular embodiment.

FIG. 1 shows a semiconductor substrate 10. A buried dielectric layer 12 is located upon base semiconductor substrate 10. A first conductor material layer 14 is located upon the buried dielectric layer 12, and a second conductor material layer 16 is located upon the first conductor material layer 14.

The semiconductor substrate 10 may comprise any of several semiconductor materials. Non-limiting examples include silicon, germanium, silicon-germanium alloy, silicon-carbon alloy, silicon-germanium-carbon alloy and compound (i.e., III-V and II-VI) semiconductor materials. Non-limiting examples of compound semiconductor materials include gallium arsenide, indium arsenide and indium phosphide semiconductor materials. Typically, the semiconductor substrate 10 has a generally conventional thickness.

The buried dielectric layer 12 may comprise any of several dielectric materials. Non-limiting examples include oxides, nitrides and oxynitrides, particularly of silicon, but oxides, nitrides and oxynitrides of other elements are not excluded. The buried dielectric layer 12 may comprise a crystalline or a non-crystalline dielectric material, with crystalline dielectric materials being highly preferred. The buried dielectric layer 12 may be formed using any of several methods. Non-limiting examples include ion implantation methods, thermal or plasma oxidation or nitridation methods, chemical vapor deposition methods and physical vapor deposition methods. Typically, the buried dielectric layer 12 comprises an oxide of the semiconductor material from which is comprised the semiconductor substrate 10. Typically, the buried dielectric layer 12 has a generally conventional thickness that may be in a range from about 1000 to about 5000 angstroms.

The first conductor material layer 14 and the second conductor material layer 16 may comprise separate and different conductor materials selected from the group including but not limited to various metals, metal alloys, metal nitrides and metal silicides. The first conductor material layer 14 and the second conductor material layer 16 may also comprise heavily doped (i.e., from about 1e18 to about 1e22 dopant atoms per cubic centimeter) monocrystalline or polycrystalline semiconductor materials such as the semiconductor materials that are disclosed above within the context of the semiconductor substrate 10.

Typically, the first conductor material layer 14 comprises a polysilicon-germanium alloy material that preferably includes from about 5 to about 10 atomic percent germanium, as well as an n dopant at a concentration from about 1e20 to about 1e21 dopant atoms per cubic centimeter. Typically, the second conductor material layer 16 comprises a polysilicon material that preferably includes an n dopant at a concentration from about 1e20 to about 1e21 dopant atoms per cubic centimeter. Typically, the first conductor material layer 14 has a thickness from about 400 to about 600 angstroms and the second conductor material layer has a thickness from about 1000 to about 50000 angstroms.

FIG. 2 shows the results of patterning the second conductor material layer 16 to form a second conductor material layer 16′ while using the first conductor material layer 14 as an etch stop layer. The second conductor material layer 16 is patterned to form the second conductor material layer 16′ while using an etch mask that is not otherwise illustrated within the schematic cross-sectional diagram of FIG. 2, in conjunction with a plasma etch method that provides generally straight sidewalls to the second conductor material layer 16′. The plasma etch method will typically use an etchant gas composition that has a specificity for etching the polysilicon material from which is comprised the second conductor material layer 16 with respect to the polysilicon-germanium alloy material from which is comprised the first conductor material layer 14. As is understood by a person skilled in the art, the first conductor material layer 14 and the second conductor material layer 16′ together form a capacitor node layer within a storage capacitor (i.e., a corrugated storage capacitor) that is formed incident to further processing of the semiconductor structure of FIG. 2.

FIG. 3 shows a capacitor dielectric layer 18 located and formed upon the semiconductor structure of FIG. 2. FIG. 3 also shows a capacitor plate layer 20 located and formed upon the capacitor dielectric layer 18. FIG. 3 finally shows a dielectric capping layer 22 located and formed upon the capacitor plate layer 20.

The capacitor dielectric layer 18 may comprise conventional capacitor dielectric materials such as oxides, nitrides and oxynitrides of silicon that have a dielectric constant from about 4 (i.e., typically a silicon oxide) to about 8 (i.e., typically a silicon nitride), measured in vacuum. Alternatively, the capacitor dielectric layer 18 may comprise generally higher dielectric constant capacitor dielectric materials having a dielectric constant from about 8 to at least about 100. Such higher dielectric constant capacitor dielectric materials may include, but are not limited to hafnium oxides, hafnium silicates, zirconium oxides, lanthanum oxides, titanium oxides, barium-strontium-titantates (BSTs) and lead-zirconate-titanates (PZTs). The capacitor dielectric layer 18 may be formed using any of several methods that are appropriate to its material of composition. Non-limiting examples include thermal or plasma oxidation or nitridation methods, chemical vapor deposition methods (including atomic layer deposition methods) and physical vapor deposition methods (including sputtering methods). The capacitor dielectric layer 18 has a thickness appropriate to a capacitor dielectric material from which is comprised the capacitor dielectric layer 18.

The capacitor plate layer 20 may comprise any of the several conductor materials from which may be comprised the first conductor material layer 14 and the second conductor material layer 16. Typically, the capacitor plate layer 20 comprises a doped polysilicon conductor material that has a thickness from about 1000 to about 50000 angstroms.

The dielectric capping layer 22 may comprise any of the several dielectric materials from which may be comprised the buried dielectric layer 12. The dielectric capping layer 16 may also be formed using any of the several methods that may be used for forming the buried dielectric layer 12. Typically, the dielectric capping layer 22 comprises a silicon oxide material, which may include but is not necessarily limited to a thermal silicon oxide material, that has a generally conventional thickness from about 500 to about 1500 angstroms.

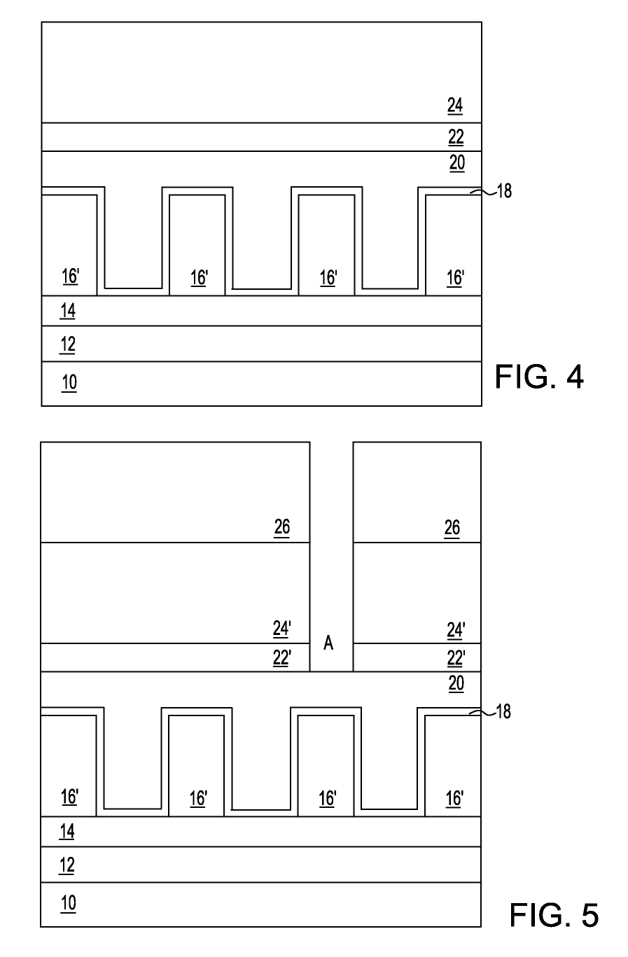

FIG. 4 shows a semiconductor layer 24 located and laminated upon the dielectric capping layer 22. The semiconductor layer 24 is located and laminated upon the dielectric capping layer 24 while using conventional layer lamination and layer transfer methods. Such conventional layer lamination and layer transfer methods may include thermally assisted methods, pressure assisted methods and aggregates of thermally assisted methods and pressure assisted methods. Such methods may in particular include lamination to the dielectric capping layer 22 of a generally thicker semiconductor substrate than the semiconductor layer 24, followed by cleavage of the generally thicker semiconductor substrate through a hydrogen ion implant induced cleavage plane, and subsequent planarization (e.g., typically but not necessarily chemical mechanical polish planarization) to form the semiconductor layer 24 of thickness from about 50 to about 2000 angstroms.

FIG. 5 first shows a photoresist layer 26 located and formed upon the semiconductor structure of FIG. 4. FIG. 5 also shows the results of using the photoresist layer 26 as an etch mask layer for etching the semiconductor layer 24 and the dielectric capping layer 22 to form a semiconductor layer 24′ and a dielectric capping layer 22′ that in an aggregate define an aperture A that exposes the capacitor plate layer 20.

The photoresist layer 26 may comprise any of several photoresist materials. Non-limiting examples include positive photoresist materials, negative photoresist materials and hybrid photoresist materials. Typically, the photoresist layer 26 comprises a positive photoresist material or a negative photoresist material that has a thickness from about 2000 to about 5000 angstroms.

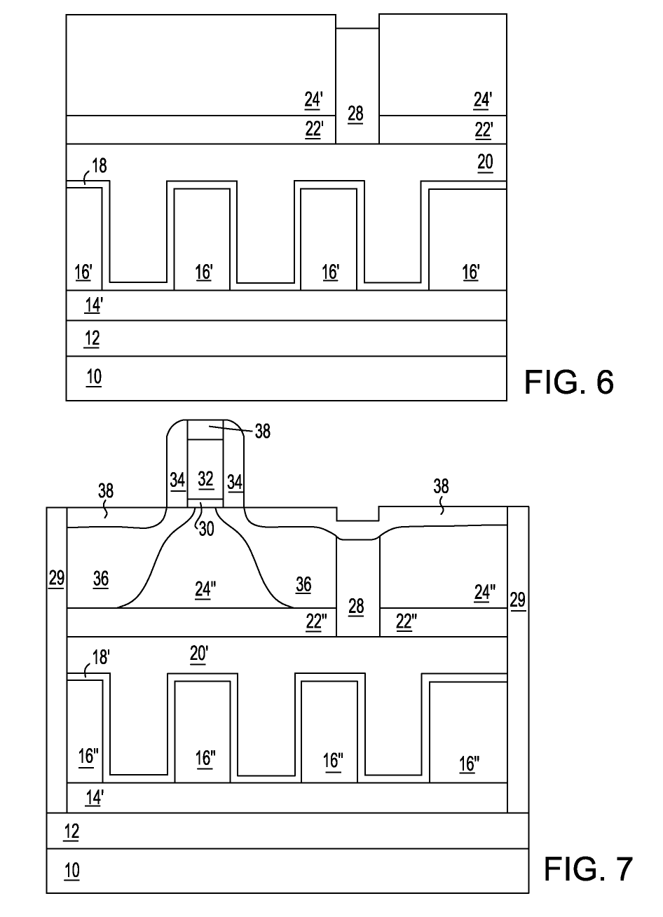

FIG. 6 first shows the results of stripping the photoresist layer 26 from the semiconductor structure whose schematic cross-sectional diagram is illustrated in FIG. 5. FIG. 6 also shows the results of forming a conductor plug layer 28 into the aperture A that is illustrated in FIG. 5.

The photoresist layer 26 may be stripped using methods and materials that are otherwise generally conventional in the semiconductor fabrication art. Non-limiting examples include wet chemical stripping methods, dry plasma stripping methods and aggregate stripping methods thereof. The conductor plug layer 28 may be formed from any of several materials from which is comprised the first conductor material layer 14, the second conductor material layer 16′ and the capacitor plate layer 20, with the proviso that the semiconductor layer 24′ and the conductor plug layer 28 are formed of sufficiently different materials such that the material from which is comprised the conductor plug layer 28 may be etched selectively with respect to the material from which is comprised the semiconductor layer 24′. Typically, the conductor plug layer 28 comprises a doped polysilicon-germanium alloy conductor material (i.e., typically having a germanium concentration from about 5 to about 10 weight percent) when the semiconductor layer 24 comprises a silicon semiconductor material, so that the conductor plug layer 28 may be selectively etched below a surface of the semiconductor layer 24′.

FIG. 7 first shows isolation regions 29 that are formed into isolation trenches that are etched through several of the corresponding layers that are illustrated within the semiconductor structure whose schematic cross-sectional diagram is illustrated in FIG. 6, the isolation trenches in particular stopping upon the buried dielectric layer 12. The foregoing etching of corresponding layers that are illustrated in FIG. 6 yields a first conductor material layer 14′, a second conductor material layer 16″, a capacitor dielectric layer 18′, a capacitor plate layer 20′, a dielectric capping layer 22″ and a semiconductor layer 24″ from the corresponding layers that are illustrated in FIG. 6. The isolation trenches are formed using etch methods that are otherwise generally conventional in the semiconductor fabrication art, including in particular reactive ion etch methods. The isolation trenches are then filled with a dielectric isolation material to form the isolation regions 29. Particular choices of dielectric isolation materials may be selected from the same group of dielectric materials that are used for forming the buried dielectric layer 12. The particular dielectric isolation materials may also be formed using methods that are analogous to the methods that are used for forming the buried dielectric layer 12. Typically, the isolation regions 29 comprise at least in part a silicon oxide material that is formed or deposited into the isolation trenches and planarized while using a generally conventional method, such as but not limited to a chemical mechanical polish planarizing method.

FIG. 7 also shows a field effect transistor located and formed into a left hand portion of the semiconductor layer 24″. The field effect transistor (which is preferably but not exclusively an n FET) comprises: (1) a gate dielectric 30 located upon the semiconductor layer 24″; (2) a gate electrode 32 located upon the gate dielectric 30; (3) a spacer 34 (illustrated as multiple layers in cross-section but intended as a single layer in plan-view) located upon a sidewall of the gate electrode 32 and the gate dielectric 30; and (4) a plurality of source/drain regions 36 located within the semiconductor layer 24″ and separated by the gate electrode 32.

Each of the foregoing layers 30, 32, 34 and 36 may comprise materials and have dimensions that are conventional in the semiconductor fabrication art. Each of the foregoing layers 30, 32, 34 and 36 may also be formed using methods that are conventional in the semiconductor fabrication art.

The gate dielectric 30 may comprise conventional dielectric materials such as oxides, nitrides and oxynitrides of silicon that have a dielectric constant from about 4 (i.e., typically a silicon oxide) to about 8 (i.e., typically a silicon nitride), measured in vacuum. Alternatively, the gate dielectric 30 may comprise generally higher dielectric constant dielectric materials having a dielectric constant from about 8 to at least about 100. Such higher dielectric constant dielectric materials may include, but are not limited to hafnium oxides, hafnium silicates, zirconium oxides, lanthanum oxides, titanium oxides, barium-strontium-titantates (BSTs) and lead-zirconate-titanates (PZTs). The gate dielectric 30 may be formed using any of several methods that are appropriate to its material of composition. Non-limiting examples include thermal or plasma oxidation or nitridation methods, chemical vapor deposition methods (including atomic layer deposition methods) and physical vapor deposition methods. Typically, the gate dielectric 30 comprises a thermal silicon oxide dielectric material that has a generally conventional thickness from about 5 to about 150 angstroms.

The gate electrode 32 may comprise materials including but not limited to certain metals, metal alloys, metal nitrides and metal silicides, as well as laminates thereof and composites thereof. The gate electrode 32 may also comprise doped polysilicon and polysilicon-germanium alloy materials (i.e., having a dopant concentration from about 1e 18 to about 1e22 dopant atoms per cubic centimeter) and polycide materials (doped polysilicon/metal silicide stack materials). Similarly, the foregoing materials may also be formed using any of several methods. Non-limiting examples include salicide methods, chemical vapor deposition methods and physical vapor deposition methods, such as, but not limited to evaporative methods and sputtering methods. Typically, the gate electrode 32 comprises a doped polysilicon material that has a thickness from about 500 to about 1500 angstroms.

The spacer 34 typically comprises a dielectric spacer material. Similarly with other dielectric structures within the instant embodiment, candidate dielectric spacer materials again include oxides, nitrides and oxynitrides of silicon. Also again, oxides, nitrides and oxynitrides of other elements are not excluded. The spacer 34 is formed using a blanket layer deposition and anisotropic etchback method that uses an anisotropic etching plasma for etching purposes. Typically, the spacer 34 comprise a silicon oxide material.

The source/drain regions 36 comprise an n dopant or a p dopant appropriate to a polarity or conductivity type of a field effect transistor desired to be fabricated incident to further processing of the semiconductor structure of FIG. 7. As indicated above, this particular embodiment preferably, but not exclusively, uses an n FET. Non-limiting examples of n dopants include arsenic dopants, phosphorus dopants, halides thereof and hydrides thereof. Non-limiting examples of p dopants include boron dopants, halides thereof and hydrides thereof. Any of the foregoing dopants may be used for forming the source/drain regions 36 within the instant embodiment. Less conventional alternative dopants are not excluded. As is understood by a person skilled in the art, the source/drain regions 36 are formed using a two step ion implant method that uses the gate electrode 32 absent the spacer 34 as a mask within a first ion implant step, followed by the gate electrode 32 with the spacer 34 as a mask within a second ion implant step.

FIG. 7 finally shows a plurality of silicide layers 38 located and formed upon the gate electrode 32 and the source/drain regions 36, and bridging to the conductor plug layer 28. The silicide layers 38 may comprise any of several silicide forming metals. Non-limiting examples of candidate silicide forming metals include nickel, cobalt, titanium, tungsten, erbium, ytterbium, platinum and vanadium silicide forming metals. Nickel and cobalt silicide forming metals are particularly common. Others of the above enumerated silicide forming metals are less common. Typically, the silicide layers 38 are formed using a salicide method. The salicide method includes: (1) forming a blanket silicide forming metal layer upon the semiconductor structure of FIG. 7 absent the silicide layers 38; (2) thermally annealing the blanket silicide forming metal layer with silicon surfaces which it contacts to selectively form the silicide layers 38 while leaving unreacted metal silicide forming metal layers on, for example, the spacers 34 and the isolation regions 29; and (3) selectively stripping unreacted portions of the silicide forming metal layers from, for example, the spacers 34 and the isolation regions 29. Typically, the silicide layers 38 comprise a nickel silicide material or a cobalt silicide material that has a thickness from about 200 to about 500 angstroms.

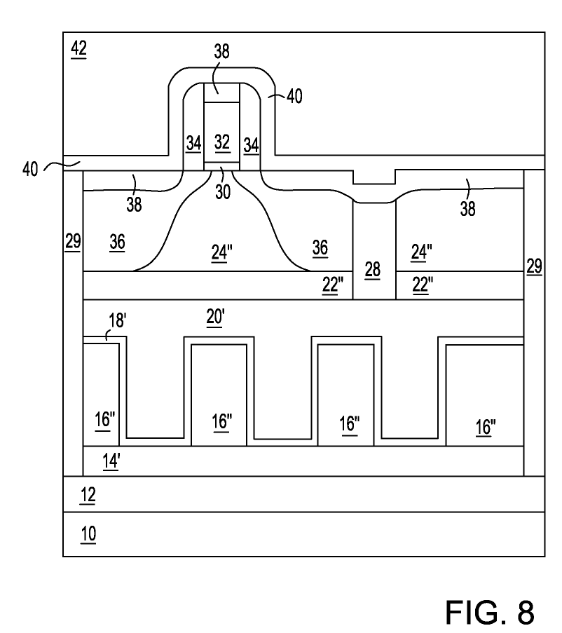

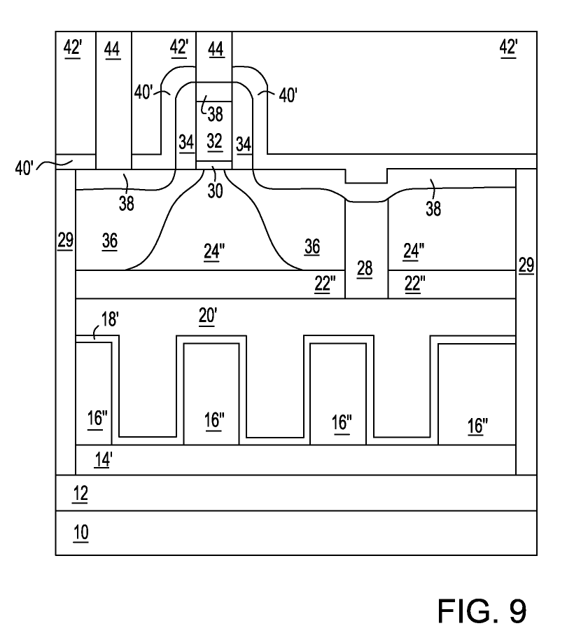

FIG. 8 shows a liner layer 40 located and formed upon the semiconductor structure of FIG. 7 and in particular covering the field effect transistor. FIG. 8 also shows an inter-level dielectric (ILD) layer 42 located and formed upon the liner layer 40.

The liner layer 40 may comprise any of several liner materials, but in particular the liner layer 40 comprises a dielectric liner material. The dielectric liner material from which is comprised the liner layer 40 may introduce a stress into a channel region of the field effect transistor located and formed within and upon the semiconductor layer 24″. The dielectric liner material may comprise any of several dielectric materials and be formed using any of several methods that are used for forming other dielectric layers within the instant embodiment, such as in particular the buried dielectric layer 12. Typically, the liner layer 40 comprises a silicon nitride material that has a thickness of from about 200 to about 1000 angstroms.

The inter-level dielectric layer 42 also comprises a dielectric material. Candidate dielectric materials are generally conventional inter-level dielectric materials such as but not limited to oxides, nitrides and oxynitrides of silicon, although oxides, nitrides and oxynitrides of other elements are not excluded. Also included are generally lower dielectric constant inter-level dielectric materials (i.e., having a dielectric constant from about 2.5 to about 4.0) such as but not limited to spin-on-glass dielectric materials, spin-on-polymer dielectric materials, carbon doped silicon oxide materials and fluorine doped silicon oxide materials. The foregoing materials may be formed using methods that are appropriate to their materials of composition. Included in particular are spin-coating methods, chemical vapor deposition methods and physical vapor deposition methods. Typically, the inter-level dielectric layer 42 comprises at least in part a silicon oxide material that has a thickness from about 1000 to about 5000 angstroms.

FIG. 9 shows a plurality of vias 44 located and formed through the inter-level dielectric layer 42 and the liner layer 40 (i.e., which are patterned to form an inter-level dielectric layer 42′ and a liner layer 40′) and contacting a plurality of silicide layers 38 located and formed upon the gate electrode 32 and a source/drain region 36. The vias 44 may be formed using any of several methods that are otherwise generally conventional in the semiconductor fabrication art. Typically, such methods will include blanket layer deposition methods followed by planarizing methods, such as chemical mechanical polish planarizing methods. The vias 44 may comprise any of several metals, metal alloys, metal nitrides and metal silicides. The vias 44 may also comprise doped polysilicon materials and polycide materials. Typically, but not exclusively, the vias 44 comprise a tungsten material.

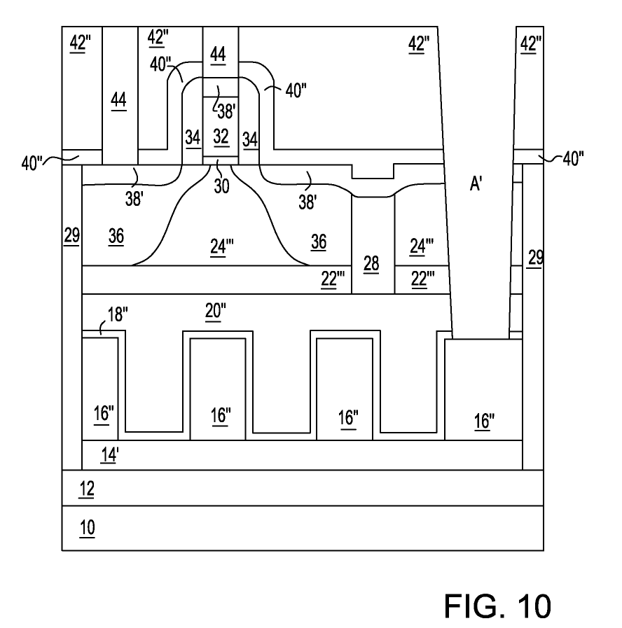

FIG. 10 shows a second aperture A′ that is formed through several overlying layers to reach the second conductor material layer 16″. Resulting from formation of the second aperture A′ is a capacitor dielectric layer 18″, a capacitor plate layer 20″, a dielectric capping layer 22′″, a semiconductor layer 24′″, a silicide layer 38′, a liner layer 40″ and an inter-metal dielectric layer 42″. The second aperture A′ may be formed using etch methods that are otherwise generally conventional in the semiconductor fabrication art. Such etch methods will generally comprise plasma etch methods that use etchant gas compositions appropriate for etching the materials from which are comprised the foregoing layers.

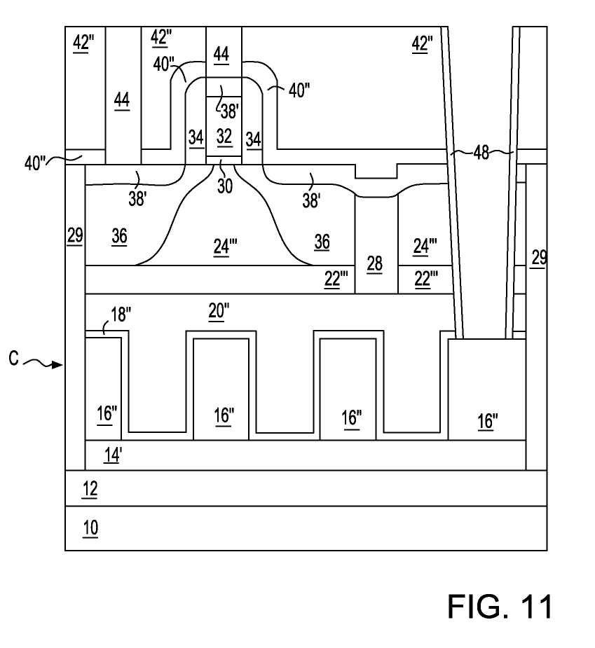

FIG. 11 shows a liner layer 48 located and formed lining the sidewalls, but not the bottom, of the second aperture A′ that is illustrated in FIG. 10. The liner layer 48 comprises a dielectric liner material. The dielectric liner material is intended to passivate conductor material sidewall surfaces that are exposed within the second aperture A′. The dielectric liner layer is formed using a blanket layer deposition and anisotropic etchback method. Typically, but not exclusively, the dielectric liner layer comprises a silicon nitride or a silicon oxynitride liner material that may be formed to a generally conventional thickness.

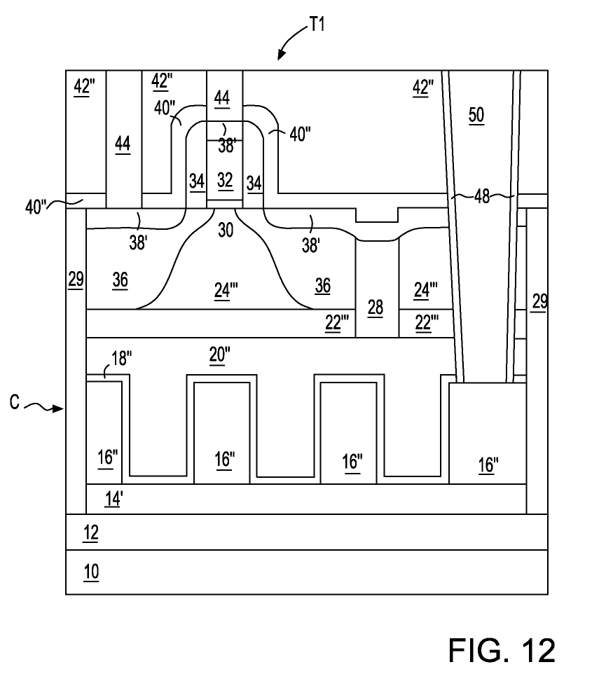

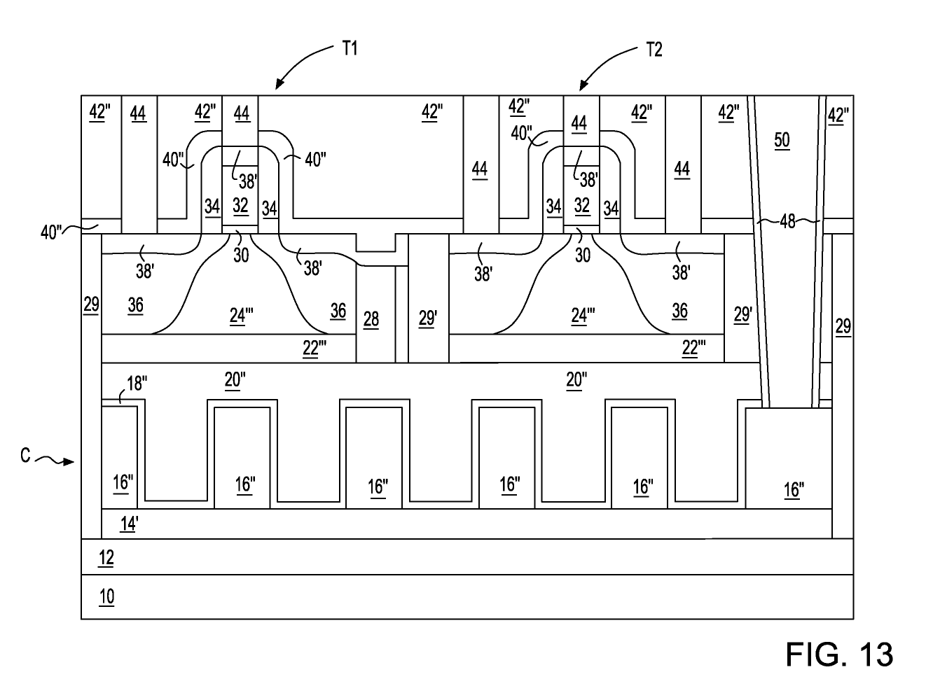

FIG. 12 shows a via 50 located and formed filling the second aperture A′. The via 50 is otherwise analogous, equivalent or identical to the vias 44 that are also illustrated within FIG. 12 within the context of materials of composition and methods of fabrication. However, the via 50 is of a generally greater depth that reaches the second conductor material layer 16″.

FIG. 12 shows a semiconductor structure in accordance with a particular embodiment of the invention that comprises a first embodiment of the invention. The semiconductor structure, which comprises a dynamic random access memory cell structure, includes both a field effect transistor T1 (i.e., a planar field effect transistor) and a capacitor C (i.e., a corrugated capacitor) located over a semiconductor substrate 10. Within the semiconductor structure, the capacitor C is located interposed between the field effect transistor T1 and the semiconductor substrate 10. A channel of the field effect transistor T1 is also located interposed between the gate electrode 32 of the field effect transistor T1 and the capacitor C. A source/drain region 36 within the field effect transistor T1 is connected to a capacitor plate layer 20″ within the capacitor C through a conductor plug layer 28. Such a configuration of the capacitor C with respect to the field effect transistor T1 and the semiconductor substrate 10, and the connection of the field effect transistor T1 with the capacitor C through the conductor plug layer 28, provides for a more space efficient semiconductor structure, such as a dynamic random access memory cell structure, in accordance with the instant embodiment.

FIG. 13 shows a schematic cross-sectional diagram of a semiconductor structure (i.e., also another dynamic random access memory cell structure) in accordance with another embodiment of the invention. This other embodiment of the invention comprises a second embodiment of the invention.

The semiconductor structure of FIG. 13 correlates with the semiconductor structure of FIG. 12, but with the addition of a second transistor T2 that is not connected to the capacitor C that is located interposed between the substrate 10 and both the first transistor T1 and the second transistor T2. Within the semiconductor structure of FIG. 13, the first transistor T1 and the second transistor T2 may be formed simultaneously. The semiconductor structure of FIG. 13 provides value insofar as an increased storage capacitance for the capacitor C may be realized by using space interposed between the semiconductor substrate 10 and both the first transistor T1 and the second transistor T2.

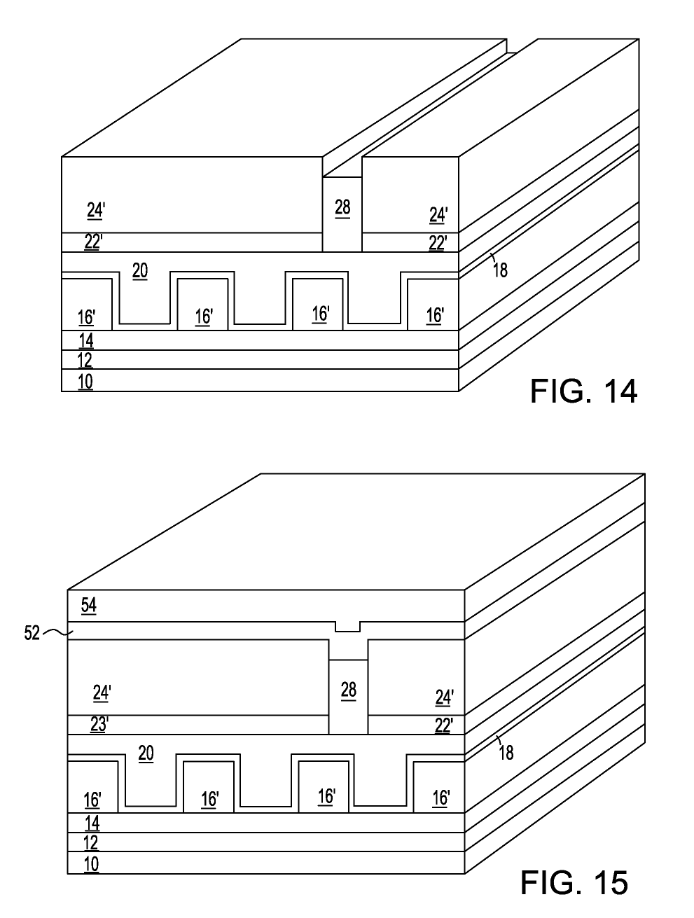

FIG. 14 to FIG. 20 show a series of schematic cross-sectional diagrams illustrating the results of progressive stages in fabricating a semiconductor structure (i.e., also another dynamic random access memory cell structure) in accordance with yet another embodiment of the invention. This yet another embodiment of the invention comprises a third embodiment of the invention. FIG. 14 shows a schematic cross-sectional diagram of the semiconductor structure at an early stage in the fabrication thereof in accordance with this yet another embodiment of the invention.

FIG. 14 shows a schematic perspective-view diagram of a semiconductor structure that corresponds with the semiconductor structure whose schematic cross-sectional diagram is illustrated in FIG. 6. Like or identical layers or structures within FIG. 6 and FIG. 14 are numerically referenced identically.

FIG. 15 shows a pad dielectric layer 52 located and formed upon the semiconductor structure of FIG. 14. FIG. 15 also shows a hard mask layer 54 located, formed and planarized upon the pad dielectric layer 52.

The pad dielectric layer 52 may comprise any of several pad dielectric materials, but will generally comprise a silicon oxide pad dielectric material, although other pad dielectric materials are not excluded. The pad dielectric layer 52 may be formed using any of several methods, of which non-limiting examples include thermal or plasma oxidation or nitridation methods, chemical vapor deposition methods and physical vapor deposition methods. Typically, the pad dielectric layer 52 has a thickness from about 100 to about 500 angstroms.

The hard mask layer 54 may comprise any of several hard mask materials, but will generally comprise a nitride hard mask material, such as but not limited to a silicon nitride hard mask material or a silicon oxynitride hard mask material. Typically, the hard mask layer 54 has planarized a thickness from about 200 to about 1000 angstroms.

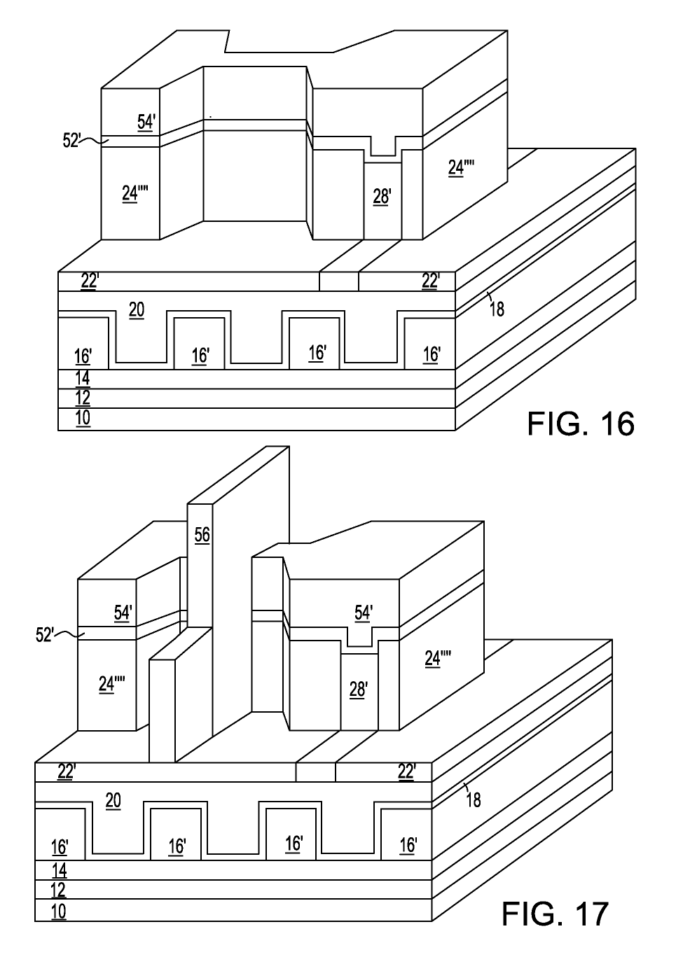

FIG. 16 shows the results of etching the hard mask layer 54, the pad dielectric layer 52, the conductor plug layer 28 and the semiconductor layer 24′ to form a corresponding hard mask layer 54′, pad dielectric layer 52′, conductor plug layer 28′ and semiconductor layer 24′″. The foregoing etching is effected at least in part while using a photoresist layer (which is not otherwise illustrated) as an etch mask layer, in conjunction with an appropriate plasma etch method that uses an appropriate etchant gas composition or combination of etchant gas compositions. Within the instant embodiment, the semiconductor layer 24′″ comprises in pertinent part a semiconductor fin that will be used within a fin-FET device that will result from further fabrication of the semiconductor structure of FIG. 16.

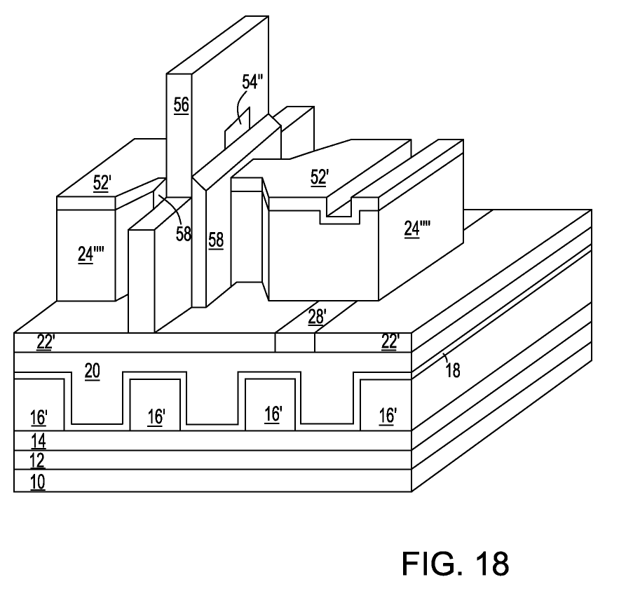

FIG. 17 shows a gate electrode 56 spanning a semiconductor fin portion of the semiconductor layer 24″″ within the semiconductor structure of FIG. 16. Also present within the schematic diagram of FIG. 17, but also not illustrated, is a gate dielectric interposed between the semiconductor fin portion of the semiconductor layer 24″″ and the gate electrode 56.

The gate dielectric that is not otherwise illustrated in FIG. 17, as well as the gate electrode 56, may comprise materials, and be formed using methods, that are generally conventional in the semiconductor fabrication art. Such materials and methods are otherwise analogous or equivalent to the methods that are used for fabricating analogous layers and structures (i.e., the gate dielectrics 30 and the gate electrodes 32) within the first embodiment as illustrated in FIG. 12 and the second embodiment as illustrated in FIG. 13.

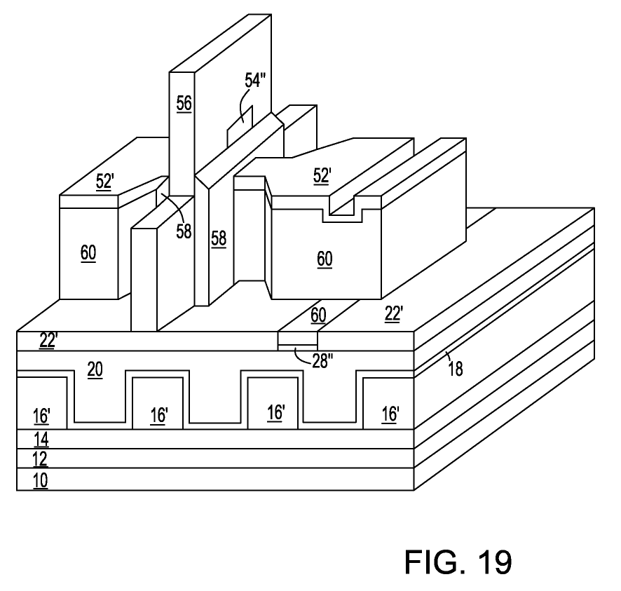

FIG. 18 first shows the results of stripping, in-part, the hard mask layer 54′ from the semiconductor structure of FIG. 17 to leave remaining a hard mask layer 54″ beneath the gate electrode 56. The hard mask layer 54′ may be stripped in-part to leave remaining the hard mask layer 54″ while using methods and materials that are otherwise generally conventional in the semiconductor fabrication art. Included in particular are wet chemical etching methods, dry plasma etching methods and aggregate of wet chemical etching methods and dry plasma etching methods.

FIG. 18 also shows a plurality of spacers 58 located adjoining the gate electrode 56. The plurality of spacers 58 may comprise materials and be formed using methods that are otherwise generally conventional in the semiconductor fabrication art. Included in particular are blanket layer deposition and anisotropic etchback methods. Typically, the plurality of spacers 58 comprises a nitride material, although the invention is not necessarily so limited.

FIG. 19 shows a plurality of silicide layers 60 located and formed upon exposed portions of the semiconductor layer 54″″ and the conductor plug layer 28′ (i.e., to thus form the conductor plug layer 28″) that are illustrated in FIG. 18. The silicide layers 60 may be formed using any of several methods. Generally, the silicide layers 60 may comprise materials, have dimensions and be formed using methods analogous, equivalent or identical to the materials, dimensions and methods used for forming the silicide layers 38 within the first embodiment, as illustrated in FIG. 12, and the second embodiment as illustrated in FIG. 13.

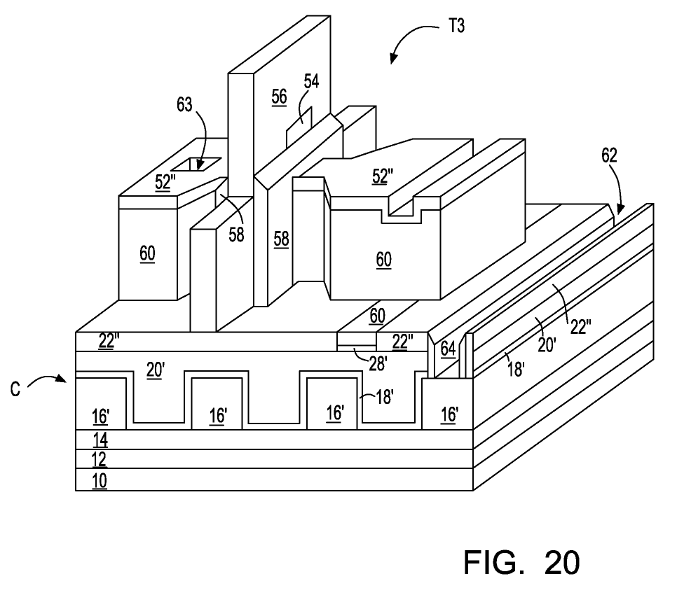

FIG. 20 shows a trench aperture 62 located and formed to expose the second conductor material layer 16′. The trench aperture 62 is lined with liner layers 64. A contact aperture 63 may also be formed through the pad dielectric layer 52′ when forming the trench aperture 62 that accesses the second conductor material layer 16′. Resulting from forming the trench aperture 62 is a capacitor dielectric layer 18′, a capacitor plate layer 20′ and a dielectric capping layer 22″. Resulting from forming the contact aperture 63 is a pad dielectric layer 52″. The trench aperture 62 and the contact aperture 63 may be formed using methods and materials analogous, equivalent or identical to the methods and materials that are used for forming the aperture A′ within the first embodiment as illustrated in FIG. 10. The liner layers 64 may also comprise materials, have dimensions and be formed using methods analogous, equivalent or identical to the liner layers 48 that are illustrated within the first embodiment within FIG. 12 and within the second embodiment within FIG. 13.

FIG. 20 shows a schematic cross-sectional diagram of a semiconductor structure in accordance with a third embodiment of the invention. Similarly with the first embodiment and the second embodiment, the semiconductor structure in accordance with the third embodiment also comprises a dynamic random access memory cell structure. The dynamic random access memory cell structure includes a fin-FET T3 located over a semiconductor substrate 10 and a capacitor C also located over the semiconductor substrate 10, where the capacitor C is located interposed between the fin-FET T3 and the semiconductor substrate 10. The capacitor C is also connected to a source/drain region (i.e., beneath silicide layer 60) of a semiconductor fin that comprises the fin-FET T3 through a conductor plug layer 28″. Similarly with the first embodiment and the second embodiment, the third embodiment also provides a space efficient semiconductor structure, such as a dynamic random access memory structure, since the capacitor C is located beneath the fin-FET T3.

The preferred embodiments of the invention are illustrative of the invention rather than limiting of the invention. Revisions and modifications may be made to methods, materials, structures and dimensions with respect to a semiconductor structure in accordance with the preferred embodiments, while still providing a semiconductor structure in accordance with the invention, and a method for fabrication thereof, further in accordance with the accompanying claims.

What is claimed is:

1. A semiconductor structure comprising:
a field effect transistor located over a substrate; and
a capacitor located over the substrate and interposed between the field effect transistor and the substrate.

2. The semiconductor structure of claim 1 wherein the field effect transistor comprises a planar field effect transistor.

3. The semiconductor structure of claim 1 wherein the field effect transistor comprises a fin-FET.

4. The semiconductor structure of claim 1 wherein a source/drain region within the field effect transistor is connected to a capacitor plate within the capacitor.

5. The semiconductor structure of claim 4 wherein the source/drain region within the field effect transistor is connected to the capacitor plate within the capacitor through a conductor plug layer.

6. The semiconductor structure of claim 5 further comprising a silicide layer located upon and spanning between the source/drain region and the conductor plug layer.

7. The semiconductor structure of claim 1 wherein the capacitor comprises a corrugated capacitor.

8. The semiconductor structure of claim 1 wherein a channel region of the field effect transistor is located between a gate electrode of the field effect transistor and the capacitor.

9. The semiconductor structure of claim 1 further comprising a second field effect transistor located over the substrate.

10. The semiconductor structure of claim 9 wherein the capacitor is also located interposed between the substrate and the second field effect transistor.

11. The semiconductor structure of claim 10 wherein the second field effect transistor is not connected to the capacitor.

12. A method for fabricating a semiconductor structure comprising:
forming a capacitor over a substrate; and
forming a field effect transistor over the substrate and over the capacitor.

13. The method of claim 12 wherein the forming the capacitor occurs prior to the forming the field effect transistor.

14. The method of claim 12 wherein the forming the field effect transistor also forms an electrical connection between the capacitor and the field effect transistor.

15. The method of claim 12 wherein the forming the capacitor forms a corrugated capacitor.

16. The method of claim 12 wherein the forming the field effect transistor forms a planar field effect transistor.

17. The method of claim 12 wherein the forming the field effect transistor forms a fin-FET.

18. A method for fabricating a semiconductor structure comprising:
forming a capacitor over a substrate;
forming a first field effect transistor over the substrate and over the capacitor; and
forming a second field effect transistor over the substrate and over the capacitor.

19. The method of claim 18 wherein the first field effect transistor and the second field effect transistor are formed simultaneously.

20. The method of claim 18 wherein:
the forming the first field effect transistor provides a connection to the capacitor; and
the forming the second field effect transistor does not provide a connection to the capacitor.
